(19) United States
(12) Patent Application Publication
(10) Pub. No.: US 2025/0210387 A1
(43) Pub. Date: Jun. 26, 2025

(54) SEMICONDUCTOR DEVICE INSPECTION DEVICE AND SEMICONDUCTOR DEVICE INSPECTION METHOD

(71) Applicant: SAMSUNG ELECTRONICS CO., LTD., SUWON-SI (KR)

(72) Inventors: Soon Kyu HWANG, Suwon-si (KR); Jin Yeol YANG, Suwon-si (KR); Jae-Min JEON, Suwon-si (KR); Je Hyun HA, Suwon-si (KR)

(21) Appl. No.: 18/814,719

(22) Filed: Aug. 26, 2024

(30) Foreign Application Priority Data
Dec. 21, 2023 (KR) 10-2023-0187928

(51) Int. Cl. H01L 21/67; G01N 1/44; G01N 21/88; G01N 21/95; H04N 23/23

(52) U.S. Cl. CPC H01L 21/67288; G01N 1/44; G01N 21/9501; H04N 23/23; G01N 2021/8887; G01N 2201/023

(57) ABSTRACT

An inspection device of a semiconductor device includes: a semiconductor device which has a first face and a second face that are opposite to each other; and a measuring device which faces the first face, and measures heat of the semiconductor device, wherein the measuring device includes: a heat generating unit which generates heat on the second face of the semiconductor device, by emitting electromagnetic waves that penetrate through the semiconductor device; and a thermal image capturing unit which generates image data about a temperature of the second face of the semiconductor device.

### CROSS-REFERENCE TO RELATED APPLICATION

This application claims priority under 35 USC § 119 to Korean Patent Application No. 10-2023-0187928 filed on Dec. 21, 2023 in the Korean Intellectual Property Office, the disclosure of which is incorporated by reference herein in its entirety.

### TECHNICAL FIELD

Embodiments of the present inventive concept relate to an inspection device of a semiconductor device, and an inspection method of the semiconductor device, and more particularly, to an inspection device of the semiconductor device and an inspection method of the semiconductor device that may detect internal defects in the semiconductor device by using infrared rays.

### DISCUSSION OF THE RELATED ART

As electronic equipment is further developed to be lighter and have increased performance, there is also a demand for semiconductor packages with decreased size and increased performance. To implement miniaturization, reduced weight, increased performance, increased capacity, and increased reliability in a semiconductor package, a semiconductor package having a structure in which a plurality of semiconductor chips are stacked is being researched and is currently under development.

In this case, there is an increasing desire to more accurately detect defects that may exist inside each of the plurality of semiconductor chips or in a bonding region between them.

### SUMMARY

According to embodiments of the present inventive concept, an inspection device of a semiconductor device includes: a semiconductor device which has a first face and a second face that are opposite to each other; and a measuring device which faces the first face, and measures heat of the semiconductor device, wherein the measuring device includes: a heat generating unit which generates heat on the second face of the semiconductor device, by emitting electromagnetic waves that penetrate through the semiconductor device; and a thermal image capturing unit which generates image data about a temperature of the second face of the semiconductor device.

According to embodiments of the present inventive concept, an inspection device of a semiconductor device includes: a semiconductor device which includes a first region, and a second region; and a measuring device which measures heat that is inside the semiconductor device, wherein the measuring device includes: a heat generating unit which generates heat to the inside of the semiconductor device, by emitting electromagnetic waves that penetrate through the semiconductor device; and a thermal image capturing unit which generates image data about temperatures of the first region and the second region.

According to embodiments of the present inventive concept, an inspection method of a semiconductor device includes: generating heat in a lower region of a semiconductor device; acquiring thermal image data about the lower region of the semiconductor device; and processing the thermal image data, wherein processing of the thermal image data includes: generating a first image from the thermal image data, generating a second image by removing noise from the first image, and generating a third image for selecting a defect of the semiconductor device from the second image.

### BRIEF DESCRIPTION OF THE DRAWINGS

The above and features of the present inventive concept will become more apparent by describing in detail example embodiments thereof with reference to the attached drawings, in which:

FIG. 1 is a diagram illustrating an inspection device of a semiconductor device according to embodiments of the present inventive concept;

FIG. 2 is a diagram illustrating the inspection device of the semiconductor device according to embodiments of the present inventive concept;

FIG. 3 is a diagram illustrating a semiconductor device that is an inspection target of the inspection device of the semiconductor device according to embodiments of the present inventive concept;

FIGS. 4, 5, 6, 7, 8, and 9 are diagrams illustrating image data measured by a measuring device according to embodiments of the present inventive concept;

FIGS. 10, 11, 12 and 13 are diagrams illustrating an image processing process by a controller according to embodiments of the present inventive concept;

FIG. 14 is a flowchart illustrating an inspection method of the semiconductor device according to embodiments of the present inventive concept; and

FIG. 15 is a diagram illustrating wavelength bands of infrared rays used in the inspection device of a semiconductor device according to embodiments of the present inventive concept.

### DETAILED DESCRIPTION OF THE EMBODIMENTS

Embodiments of the present inventive concept will be described in detail below with reference to the accompanying drawings. The same reference numerals will be used for the same components in the drawings and specification, and repeated description thereof will not be provided.

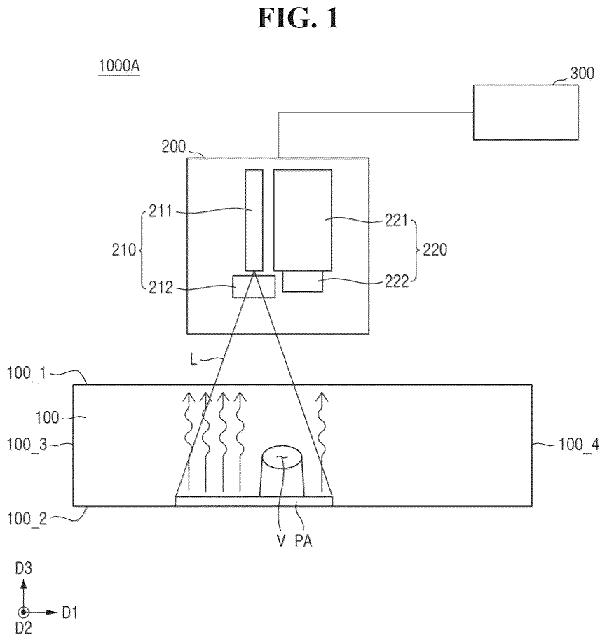

FIG. 1 is a diagram illustrating an inspection device of a semiconductor device according to embodiments of the present inventive concept.

Referring to FIG. 1, an inspection device 1000A of the semiconductor device according to embodiments of the present inventive concept may include a semiconductor device 100, a measuring device 200, and a controller 300.

The semiconductor device 100 may have a first face 100_1 and a second face 100_2 that are opposite to each other. The semiconductor device 100 may further include a third face 100_3 and a fourth face 100_4 that connect the first face 100_1 and the second face 100_2 to each other and are opposite to each other. The first face 100_1 and the second face 100_2 may be an upper face and a lower face of the semiconductor device 100, respectively. Each of the third face 100_3 and the fourth face 100_4 may be a first side face and a second side face of the semiconductor device 100.

In embodiments of the present inventive concept, first and second directions D1 and D2 may refer to directions that are parallel to the upper face of the semiconductor device 100 and may perpendicularly intersect to each other. A third direction D3 may refer to a vertical direction that is perpendicular to each of the first and second directions D1 and D2.

For example, the semiconductor device 100 may include a first region in which a defect is formed, and a second region in which a defect is not formed. For example, the defect may be voids and/or cracks. Referring to FIG. 1, the first region may be a region in which a void V is formed, and the second region may be an internal region of the semiconductor device 100 in which the void V is not formed.

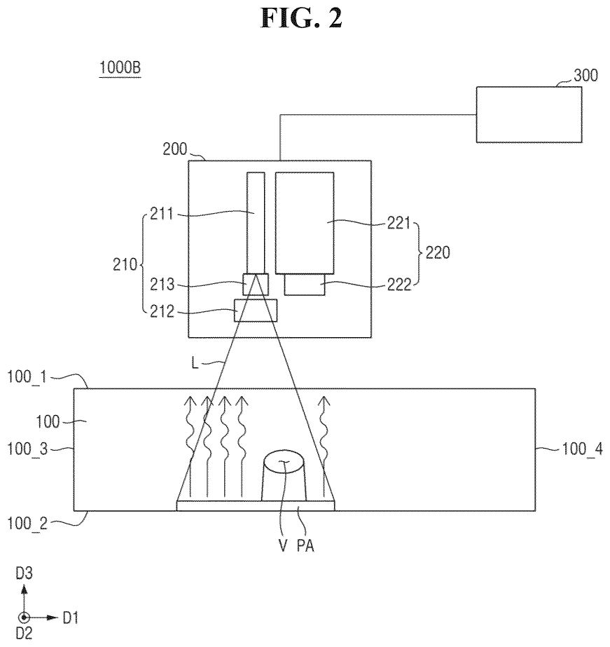

In addition, the void V shown in FIGS. 1 and 2 is an example, and the position, shape, and number of voids V are not limited to those shown in the drawings. Although FIGS. 1 and 2 only show the void V as defects of the semiconductor device 100, defects are not limited thereto, and for example, cracks may be formed in the semiconductor device 100.

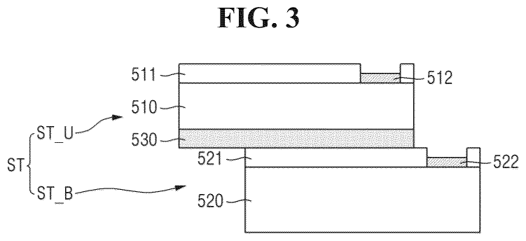

The semiconductor device 100 may include, for example, but not limited to, silicon (Si). A specific shape of the semiconductor device 100 will be described later using FIG. 3.

The measuring device 200 is disposed on the first face 100_1 of the semiconductor device 100, and may measure the heat of the semiconductor device 100. The measuring device 200 may include a heat generating unit 210 and a thermal image capturing unit 220.

The heat generating unit 210 may generate heat on the second face 100_2 of the semiconductor device 100 by emitting light L that penetrates through the semiconductor device 100. The heat generating unit 210 may include a laser generator 211 and a beam shaper 212.

In an embodiment of the present inventive concept, the heat generating unit 210 may be a light emitter.

The laser generator 211 may emit a laser beam toward the second face 100_2 of the semiconductor device 100. The laser generator 211 may emit electromagnetic waves having a wavelength band that penetrates through the semiconductor device 100, for example, infrared rays L of a medium wavelength band. For example, the wavelength band may range from about 1 μm to about 5 μm.

The beam shaper 212 may adjust the shape of the laser beam that is emitted to the second face 100_2 of the semiconductor device 100. The beam shaper 212 may be disposed between the laser generator 211 and the first face 100_1 of the semiconductor device 100. The beam shaper 212 may increase a measurement efficiency, by adjusting the shape of the laser beam to match the shape of the second face 100_2 of the semiconductor device 100 which is irradiated by the laser beam.

For example, a shape modulation lens, which modulates the shape of a laser beam into a linear laser beam, may be used. Although the shape modulation lens may be a cylindrical lens, various shape modulation lenses may be used, without being limited to the cylindrical lens. Further, for example, the shape of the laser beam may be adjusted, using a diffractive optical system (DOE).

The heat generating unit 210 may further include an LED illumination and a lamp, in addition to the laser generator 211 for heating the inside of the semiconductor device 100, which is a target structure.

A thermal image capturing unit 220 may generate image data about a temperature distribution on the second face 100_2 of the semiconductor device 100. The thermal image capturing unit 220 may include a thermal image camera 221 and an infrared filter 222.

The thermal image camera 221 may detect the heat on the second face 100_2 of the semiconductor device 100 that is generated by the infrared rays L. The infrared filter 222 may be disposed between the thermal image camera 221 and the first face 100_1 of the semiconductor device 100.

For example, the thermal image capturing unit 220 may detect the heat inside the semiconductor device 100 that is generated by the infrared rays L having a wavelength band of about 1 μm to about 5 μm. The wavelength band of the infrared ray L measured by the thermal image camera 221 may be adjusted to, for example, a range of about 3 μm to 5 about μm, by the infrared filter 222.

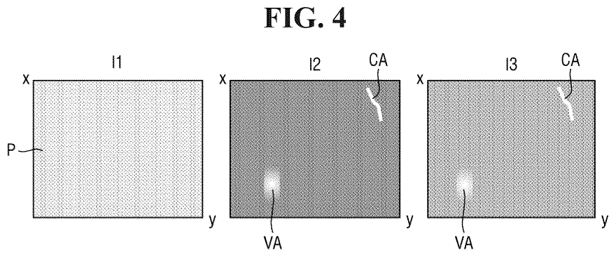

The thermal image capturing unit 220 may generate image data (I1, I2, and I3 of FIG. 4) about the temperatures of the first region in which a defect, for example, a void V is formed, and the second region in which the void V is not formed. In the image data (I1, I2, and I3 of FIG. 4), the temperature of the region corresponding to the first region may be shown to have a lower temperature than the temperature corresponding to the second region. This will be described below by using FIGS. 4 to 9.

A projection region PA may be a region of the semiconductor device 100 that is irradiated by the infrared rays L that are emitted from the heat generating unit 210.

For example, the measuring device 200 may be disposed to be adjacent to the upper face of the semiconductor device 100, that is, the first face 100_1. In this case, the projection region PA may be adjacent to the lower face of the semiconductor device 100, that is, the second face 100_2.

As an example, the measuring device 200 may be disposed to be adjacent to a first side face of the semiconductor device 100, that is, the third face 100_3. In this case, the projection region PA may be adjacent to the second side face of the semiconductor device 100, that is, the fourth face 100_4.

The control unit (or, e.g., control circuit) 300 may perform image processing on the image data generated by the thermal image capturing unit 220.

The control unit 300 may receive the image data from the thermal image capturing unit 220. The control unit 300 compresses the image data that is transmitted from the thermal image capturing unit 220 to generate an image, removes noise from the generated image, and may detect defects in the semiconductor device 100, accordingly.

For this purpose, the control unit 300 may be provided in the form of a recording medium that stores computer-executable commands. The commands may be stored in the form of program code. When the commands are executed by the processor, a program module is generated, and the operations of the disclosed embodiments may be performed. The recording medium may be implemented as a computer-readable recording medium. The computer-readable storage medium may include any type of storage medium in which commands that may be decoded by a computer are stored. For example, the recording medium may include a ROM (Read Only Memory), a RAM (Random Access Memory), a magnetic tape, a magnetic disk, a flash memory, an optical data storage device, and the like. The image processing process of the control unit 300 will be described below using FIGS. 9 to 12.

FIG. 2 is a diagram illustrating an inspection device of the semiconductor device according to embodiments of the present inventive concept. For convenience of explanation, differences from the inspection device of the semiconductor device described with reference to FIG. 1 will be mainly explained.

Referring to FIG. 2, the heat generating unit 210 of an inspection device 1000B of the semiconductor device according to embodiments of the present inventive concept may further include an infrared filter 213.

The infrared filter 213 may be disposed between the laser generator 211 and the first face 100_1 of the semiconductor device 100. Further, the infrared filter 213 may be disposed between the laser generator 211 and the beam shaper 212.

The infrared filter 213 may filter the wavelength band of the infrared ray L that are generated by the laser generator 211 with the infrared ray L of a narrower wavelength band. For example, when the wavelength band of the infrared ray L generated by the laser generator 211 is wider than the above-mentioned about 1 μm to about 5 μm wavelength band, the infrared filter 213 may adjust the wavelength band of the infrared rays L such that the semiconductor device 100 is irradiated with the infrared ray L of the about 1 μm to about 5 μm wavelength band. Further, for example, the semiconductor device 100 may be irradiated with infrared rays L having a wavelength band narrower than the above-mentioned above 1 μm to about 5 μm wavelength band, for example, a wavelength band of about 800 nm to about 1000 nm, by the infrared filter 213.

FIG. 3 is a diagram illustrating a semiconductor device that is an inspection target of the inspection device of the semiconductor device according to embodiments of the present inventive concept.

Referring to FIG. 3, the stack structure ST may include an upper structure ST_U and a lower structure ST_B that are stacked on each other. The stack structure ST may further include a bonding layer 530 that bonds the upper structure ST_U and the lower structure ST_B to each other. The stack structure ST shows the semiconductor device 100 described above, and the semiconductor device 100 that is to be inspected is not limited to the stack structure ST shown in FIG. 3.

The upper structure ST_U may include an upper semiconductor chip 510, an upper insulating layer 511, and an upper conductive pad 512. The upper insulating layer 511 may be disposed on the upper face of the upper semiconductor chip 510, and may expose the upper conductive pad 512.

The upper semiconductor chip 510 may be a semiconductor chip including silicon (Si). For example, the upper semiconductor chip 510 may be a volatile memory chip such as a DRAM (Dynamic Random Access Memory) or a SRAM (Static RAM), or may be a non-volatile memory chip such as a PRAM (Phase-change RAM), a MRAM (Magneto resistive RAM), a FeRAM (Ferroelectric RAM) or a RRAM (Resistive RAM), or may be an HBM (High Bandwidth Memory) memory chip in which a plurality of DRAM memory chips are stacked on each other. However, the present inventive concept is not limited thereto.

The upper insulating layer 511 may include, for example, an insulating material such as silicon oxide. When the upper insulating layer 511 is a solder resist, the upper insulating layer 511 may include, but not limited to, a photosensitive material.

The upper conductive pad 512 may include a metal material. For example, the upper conductive pad 512 may include at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The lower structure ST_B may include a lower semiconductor chip 520, a lower insulating layer 521, and a lower conductive pad 522. The lower insulating layer 521 is disposed on the upper face of the lower semiconductor chip 520, and may expose the lower conductive pad 522.

The lower semiconductor chip 520 may be a semiconductor chip including silicon (Si). For example, the lower semiconductor chip 520 may be a volatile memory chip such as a DRAM (Dynamic Random Access Memory) or a SRAM (Static RAM), or may be a non-volatile memory chip such as a PRAM (Phase-change RAM), a MRAM (Magneto resistive RAM), a FeRAM (Ferroelectric RAM) or a RRAM (Resistive RAM), or may be an HBM (High Bandwidth Memory) memory chip in which a plurality of DRAM memory chips are stacked on each other. However, the present inventive concept is not limited thereto.

The lower insulating layer 521 may include, for example, an insulating material such as silicon oxide. When the lower insulating layer 521 is a solder resist, the lower insulating layer 521 may include, but not limited to, a photosensitive material.

The lower conductive pad 522 may include a metal material. For example, the lower conductive pad 522 may include at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C).

The bonding layer 530 may include, for example, an insulating material such as silicon oxide; however, the present inventive concept is not limited thereto. The bonding layer 530 may be, for example, a DAF (Direct Adhesive Film). The bonding layer 530 may include an insulating polymer. For example, the bonding layer 530 may include an epoxy resin and a filler.

For example, the filler may use at least one or more of silica (SiO₂), alumina (Al₂O₃), silicon carbide (SiC), barium sulfate (BaSO₄), talc, mud, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and/or calcium zirconate (CaZrO₃). In addition, the material of the filler is not limited thereto, and the filler may include a metal material and/or an organic material.

The bonding layer 530 may serve to insulate the semiconductor chips 510 and 520 from each other and/or to bond them together.

For example, defects such as voids and/or cracks may occur inside each of the upper structure ST_U and the lower structure ST_B or in the bonding layer 530 that is between the upper and lower structures ST_U and ST_B.

In the related art, a method has been used in which thermal reactions related to defects inside the semiconductor device are indirectly sensed, by measuring the heat that is generated on the surface of the semiconductor device by laser light with a thermal image camera.

According to embodiments of the present inventive concept, thermal reactions associated with defects of the semiconductor device may be more directly sensed, by utilizing infrared rays of a wavelength band that is transmitted through the interior of the semiconductor device. As a result, defects occurring inside each of a plurality of semiconductor devices or in a bonding region that is between the semiconductor devices may be detected more accurately.

FIGS. 4 to 9 are diagrams illustrating image data that is measured by the measuring device according to embodiments of the present inventive concept.

Referring to FIG. 4, the thermal image capturing unit 220 may obtain three pieces of first to third image data I1, I2, and I3 by a laser trigger signal that is generated from the heat generating unit 210.

For example, the first to third image data I1, I2, and I3 may be obtained just before the semiconductor device 100 is heated by the infrared rays L, just after heated, and after heated.

The first image data I1 corresponds to image data just before the semiconductor device 100 is heated. A plurality of patterns P may exist outside the semiconductor device 100. The plurality of patterns P may be a temperature difference between regions of the semiconductor device 100 before heating the semiconductor device 100, which is a target structure.

The second image data I2 corresponds to image data just after the semiconductor device 100 is heated. The third image data I3 corresponds to image data after a predetermined time has elapsed after the semiconductor device 100 has been heated.

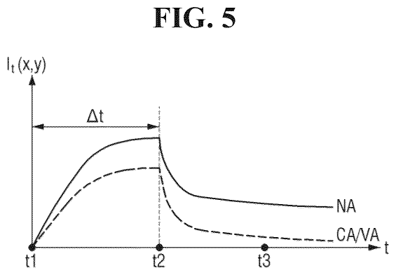

FIG. 5 is a diagram that shows a temperature Iₜ(x, y) distribution of a crack region CA, a void region VA, and a normal region NA except these regions, after the semiconductor device 100 is heated by a laser for a predetermined time At from just before heating (t1). Referring to FIG. 5, the temperature Iₜ(x, y) of the crack region CA and the void region VA just after the semiconductor device 100 is heated (t2) and the temperature Iₜ(x, y) of the crack region CA and the void region VA after the semiconductor device 100 is heated (t3) may be shown to be lower than that of the normal region NA. The crack region CA and the void region VA are not projected by laser irradiation, and may indicate that a small amount of heat is generated in the measurement region of the thermal image capturing unit 220.

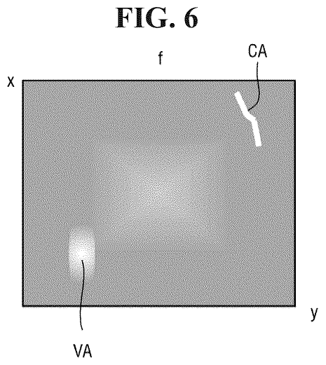

Referring to FIG. 6, a thermal cumulative image f may be obtained by calculating the following Equation (1) for the first to third image data I1, I2, and I3.

In Equation (1), I1(x, y) may mean temperature values corresponding to each pixel at specific positions with regard to x and y coordinates just before heating. I2(x, y) may mean temperature values corresponding to each pixel at specific positions with regard to x and y coordinates just after heating. I3(x, y) may mean temperature values corresponding to each pixel at specific positions with regard to x and y coordinates after heating. Symbol ‘abs’ means an absolute value.

Referring to Equation (1), temperature values f(x, y) corresponding to each pixel at the specific positions with regard to x and y coordinates of the heat accumulation image f may be obtained through a difference between the temperature value just after heating and the temperature value just before heating, and a difference between the temperature value after heating and the temperature value just before heating.

$$Equation ( 1 )$$

$$f ( x , y ) = 1 / 2 \times [ abs \{ I 2 ( x , y ) - I 1 ( x , y ) \} + abs \{ I 3 ( x , y ) - I 1 ( x , y ) \} ]$$

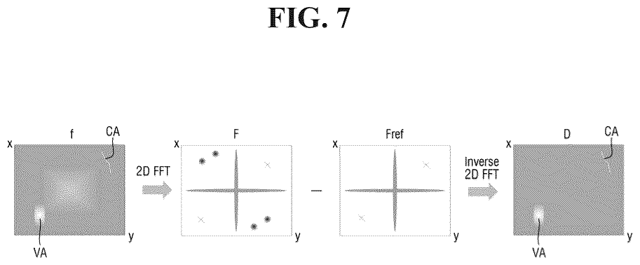

Referring to FIG. 7, a thermal pattern image D regarding a defect of the semiconductor device 100 may be tracked by applying a 2D FFT (2D Fast Fourier Transform) calculation to the thermal accumulation image f.

For example, the internal pattern component Fref may be deleted from the 2D FFT-transformed thermal accumulation image f. Thereafter, by applying an inverse 2D fast Fourier transform (2D FFT) calculation, it is possible to track the thermal pattern image D from which residual heat components due to the internal structure of the semiconductor device 100 have been removed.

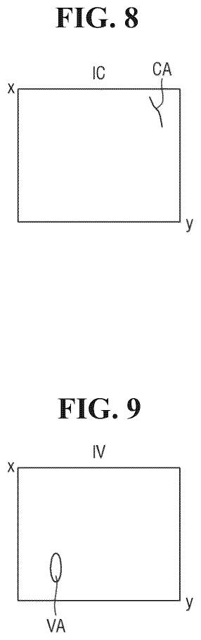

Referring to FIG. 8, edge filtering may be performed from the thermal pattern image D to track the crack image IC. The crack image IC may be obtained by tracking a sudden point of change in the surface temperature of the semiconductor device 100, which is the target structure. Sobel algorithm, Holder index, or the like may be used for the edge filtering.

Referring to FIG. 9, an auto-thresholding algorithm may be performed on regions to which edge filtering is not applied from the thermal pattern image D to track the void image IV. The void image IV may be obtained by tracking points on which the surface temperature suddenly changes in a region other than the crack region of the semiconductor device 100, which is the target structure.

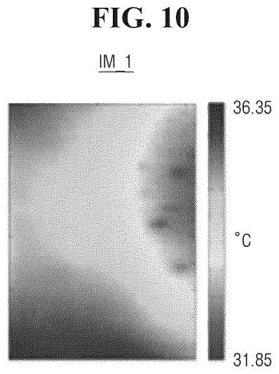

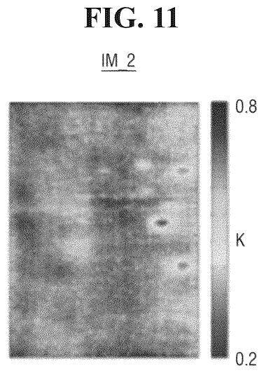

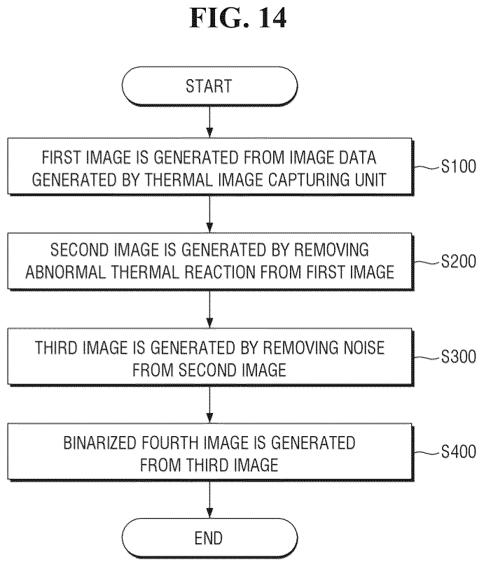

FIGS. 10 to 13 are diagrams illustrating an image processing process by the control unit according to embodiments of the present inventive concept. FIG. 14 is a flowchart for explaining an inspection method of the semiconductor device according to some embodiments.

Referring to FIGS. 10 and 14, the control unit 300 may process the image data (I1, I2, and I3 of FIG. 4) that is generated by the thermal image capturing unit 220.

The control unit 300 may generate the first image IM_1 from the image data (I1, I2, and I3 of FIG. 4) that is generated by the thermal image capturing unit 220 (S100).

The first image IM_1 may be formed by compressing a plurality of image data that is generated by the thermal image capturing unit 220 into one image.

The first image IM_1 may represent a temperature distribution inside the semiconductor device 100 as temperature values of pixels. The temperature value may have a range of about 31.85° C. to about 36.35° C. Therefore, in the first image IM_1, the temperature distribution inside the semiconductor device 100 may be known from each color.

The plurality of image data may be compressed into a single image that visualizes an amplitude of frequency and a phase change according to thermal changes, in conjunction with the laser heating frequency, by a lock-in algorithm.

Next, referring to FIGS. 11 and 14, a second image IM_2 may be generated, by removing the abnormal thermal reaction from the first image IM_1 (S200).

The second image IM_2 may be generated from the first image IM_1 via high-pass filtering and a pattern recognition algorithm. The second image IM_2 may be formed by removing a specific thermal reaction that is caused by the non-uniformity of the material of the semiconductor device 100 and the sample pattern from the first image IM_1. For example, the abnormal thermal reaction may be removed, by applying the high pass filter to the first image IM_1.

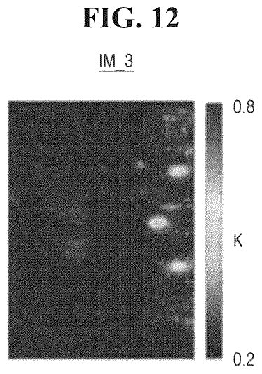

Then, referring to FIGS. 12 and 14, a third image IM_3 may be generated by removing noise from the second image IM_2 (S300).

The third image IM_3 may be generated by applying a noise removal filter such as a median filter to the second image IM_2. For example, the noise removal filter may be effective in removing pepper and salt noise.

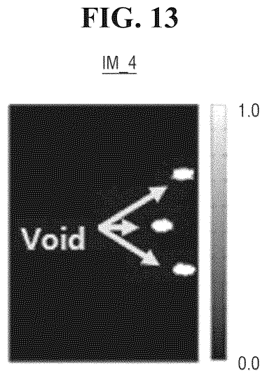

Next, referring to FIGS. 13 and 14, to select defects of the semiconductor device 100 from the third image IM_3, a binarized fourth image IM_4 may be generated (S400).

The fourth image IM_4 may be formed by performing rule-based categorization on the third image IM_3.

The fourth image IM_4 may be generated by selecting defects of the semiconductor device 100 according to the limit sample definition and by visualizing the defects. For example, a normal case and an abnormal case are classified depending on the presence or absence or size of voids, binarization processing is performed into “1” or “0”, and a fourth image IM_4 may be generated based on this.

By performing the defect inspection image processing on such image data, it is possible to extract a defective region in the inspection region on the semiconductor device 100 and visualize the defect shape.

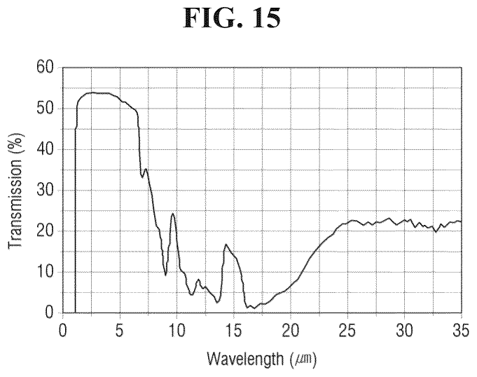

FIG. 15 is a diagram illustrating wavelength bands of infrared rays that are used in the inspection device of the semiconductor device according to embodiments of the present inventive concept.

Referring to FIG. 15, it may be seen that the transmittance of infrared rays of the medium wavelength band in the range of about 1 μm to about 5 μm on silicon (Si) is about 50% to about 55%. In embodiments of the present inventive concept, defects existing inside the semiconductor device may be detected more accurately, by using the measuring device 200 that emits and measures such infrared rays of the medium wavelength band.

While the present inventive concept has been described with reference to embodiments thereof, it will be understood by those of ordinary skill in the art that various changes in form and details may be made thereto without departing from the spirit and scope of the present inventive concept.

What is claimed is:

1. An inspection device of a semiconductor device, the inspection device comprising:
a semiconductor device which has a first face and a second face that are opposite to each other; and
a measuring device which faces the first face, and measures heat of the semiconductor device,
wherein the measuring device includes:
a heat generating unit which generates heat on the second face of the semiconductor device, by emitting electromagnetic waves that penetrate through the semiconductor device; and
a thermal image capturing unit which generates image data about a temperature of the second face of the semiconductor device.

2. The inspection device of the semiconductor device of claim 1,
wherein the heat generating unit includes:
a laser generator which emits a laser beam toward the second face of the semiconductor device; and
a beam shaper which adjusts a shape of the laser beam that is emitted to the second face of the semiconductor device.

3. The inspection device of the semiconductor device of claim 2,
wherein the heat generating unit further includes:
a first infrared filter which is disposed between the laser generator and the first face of the semiconductor device.

4. The inspection device of the semiconductor device of claim 1,
wherein the thermal image capturing unit includes:
a thermal image camera which detects heat on the second face; and
a second infrared filter which is disposed between the thermal image camera and the first face of the semiconductor device.

5. The inspection device of the semiconductor device of claim 1,
wherein the semiconductor device includes a first region and a second region,
wherein the thermal image capturing unit generates image data about the temperatures of the first region and the second region, and
wherein, if there is a defect in the first region, a temperature of the first region is different from a temperature of the second region.

6. The inspection device of the semiconductor device of claim 5,
wherein the temperature of a region corresponding to the first region is lower than the temperature of a region corresponding to the second region.

7. The inspection device of the semiconductor device of claim 1, further comprising:
a projection region which is adjacent to the second face of the semiconductor device, and which is irradiated by electromagnetic waves that are emitted from the heat generating unit.

8. The inspection device of the semiconductor device of claim 1, further comprising:
a controller which processes the image data that is generated by the thermal image capturing unit,
wherein the controller
generates a first image from the image data that is generated by the thermal image capturing unit,
generates a second image by removing a specific thermal response from the first image,
generates a third image by removing noise from the second image, and
generates a binarized fourth image to select defects of the semiconductor device from the third image.

9. The inspection device of the semiconductor device of claim 1,
wherein the electromagnetic waves have a wavelength band of about 1 um to about 5 um.

10. The inspection device of the semiconductor device of claim 1,
wherein the semiconductor device includes silicon (Si).

11. An inspection device of a semiconductor device, the inspection device comprising:
a semiconductor device which includes a first region, and a second region; and
a measuring device which measures heat that is inside the semiconductor device,
wherein the measuring device includes:
a heat generating unit which generates heat to the inside of the semiconductor device, by emitting electromagnetic waves that penetrate through the semiconductor device; and
a thermal image capturing unit which generates image data about temperatures of the first region and the second region.

12. The inspection device of the semiconductor device of claim 11,
wherein the semiconductor device has an upper face and a lower face that are opposite to each other,
the measuring device is disposed adjacent to the upper face, and
the inspection device further comprises a projection region which is adjacent to the lower face, and which is irradiated by infrared rays that are emitted from the heat generating unit.

13. The inspection device of the semiconductor device of claim 11,
wherein the semiconductor device has an upper face and a lower face that are opposite to each other, and a first side face and a second side face that connect the upper face and the lower face to each other and are opposite to each other,
the measuring device is disposed adjacent to the first side face, and
the semiconductor device further comprises a projection region which is adjacent to the second side face, and which is irradiated by infrared rays that are emitted from the heat generating unit.

14. The inspection device of the semiconductor device of claim 11,
wherein in the image data, if there is a defect in the first region and no defect in the second region, a temperature of a region corresponding to the first region is lower than a temperature of a region corresponding to the second region.

15. The inspection device of the semiconductor device of claim 11,
wherein the heat generating unit includes:
a laser generator which emits a laser beam toward the semiconductor device;
a beam shaper which adjusts a shape of the laser beam that is emitted to the semiconductor device; and
a first infrared filter which is disposed between the laser generator and the semiconductor device,
wherein the thermal image capturing unit includes:
a thermal image camera which detects infrared rays, and
a second infrared filter which is disposed between the thermal image camera and the semiconductor device.

16. The inspection device of the semiconductor device of claim 11, further comprising:
a controller which processes the image data that is generated by the thermal image capturing unit,
wherein the controller
generates a first image by compressing the image data that is generated by the thermal image capturing unit,
generates a second image by removing noise from the first image, and
generates a binarized third image to select defects of the semiconductor device from the second image.

17. An inspection method of a semiconductor device, the method comprising:
generating heat in a lower region of a semiconductor device;
acquiring thermal image data about the lower region of the semiconductor device; and
processing the thermal image data,
wherein processing of the thermal image data includes:
generating a first image from the thermal image data,
generating a second image by removing noise from the first image, and
generating a third image for selecting a defect of the semiconductor device from the second image.

18. The inspection method of the semiconductor device of claim 17,
wherein the generating of the first image further includes:
compressing the thermal image data.

19. The inspection method of the semiconductor device of claim 17,
wherein the generating of the second image further includes;
removing a thermal reaction from the first image.

20. The inspection method of the semiconductor device of claim 17,
wherein the generating of the third image further includes:
performing binarization processing on the second image.
